(19) United States
(12) Patent Application Publication
(10) Pub. No.: US 2022/0030702 A1
(43) Pub. Date: Jan. 27, 2022

(54) SECURE EMBEDDED WATERMARKS

(71) Applicant: International Business Machines Corporation, Armonk, NY (US)

(72) Inventors: Mark E. Maresh, Wake Forest, NC (US); Michael J. Whitney, Cary, NC (US); Juan F. Vargas, Cary, NC (US)

(21) Appl. No.: 16/939,006

(22) Filed: Jul. 26, 2020

(51) Int. Cl. H05K 1/02

(52) U.S. Cl. CPC H05K 1/0269; B42D 25/333

(57) ABSTRACT

An article comprises a superficial watermark located on a first surface. The article also comprises an embedded watermark that is embedded within the article. The embedded watermark may be viewed by an X-ray camera. A method comprises applying a metal-containing mixture to an inner layer of an article, resulting in an embedded watermark within the article. The method also comprises analyzing the properties of metal particles within the mixture. The method also comprises recording the first property.

### BACKGROUND

The present disclosure relates to watermarks, and more specifically, to watermarks embedded within articles.

Watermarks are sometimes used to identify articles. Identifying an article, as used herein, may refer to determining an identity of an article or certifying an article as genuine. Watermarks may be used to identify the class into which an article falls, identify the particular article, or authenticate an article as certified. Some articles are manufactured with watermarks embedded within the article. Articles with multiple layers may be manufactured with a metal watermark between those layers. That metal watermark may be viewed using an x-ray device, and may then be used to identify the article.

### SUMMARY

Some embodiments of the present disclosure can be illustrated as an article comprising a superficial watermark located on a first surface. The article also comprises an embedded watermark embedded within the article. The embedded watermark may be viewed by an X-ray camera.

Some embodiments of the present disclosure can also be illustrated as an article that comprises an embedded watermark within the article. The embedded watermark may comprise an identifiable mixture of metal particles.

Some embodiments of the present disclosure can also be illustrated as a method comprising applying a metal-containing mixture to an inner layer of an article. This application results in an embedded watermark within the article. The method may also comprise analyzing a first property of metal particles of the mixture. The method may also comprise recording the first property.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts an article with a watermark embedded between two layers of the article.

FIG. 2A depicts a first view of an article that displays a watermark on the surface of the article.

FIG. 2B depicts a second view of an article that displays a watermark embedded within the article.

FIG. 2C depicts a third view of an article that displays the watermark on the surface of the article and the watermark embedded within the article.

FIG. 3 depicts a method of analyzing an embedded watermark in accordance with embodiments of the present disclosure.

FIG. 4 depicts a method of recording properties of an embedded watermark for use in identification purposes, in accordance with the embodiments of the present disclosure.

FIG. 5 depicts the representative major components of a computer system that may be used in accordance with embodiments.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the present disclosure relate to watermarks, more particular aspects relate to watermarks embedded within articles. While the present disclosure is not necessarily limited to such applications, various aspects of the disclosure may be appreciated through a discussion of various examples using this context.

Watermarks are sometimes used to identify the properties of an item or to certify an item's authenticity. These processes may be referred to herein as “identifying” an article. Watermarks, as used herein, may refer to a design, such as a symbol, that is applied to an item for these purposes. The information that is identifiable by a watermark is often, but not always, not commonly identifiable by the design of the watermark. For example, a triangle watermark may be used to identify the calendar month during which a physical product was manufactured, and a very small section of text may be used to certify a piece of currency as authentic. On the other hand, sometimes a watermark may take the form of a serial number that is not visible to the naked eye (for example, the watermark may only be visible using an x-ray camera or when exposed to ultraviolet light), and is used to identify a unique item.

The items to which a watermark is applied may be referred to herein as “articles.” An article may describe a physical product, a piece of currency, a document, product packaging, and other such items that are otherwise consistent with the embodiments of the present disclosure.

Historically, watermarks have been included on the surface of articles for identification or certification purposes. However, watermarks placed on the surface of articles (sometimes referred to herein as “superficial watermarks”) can be relatively easily viewed by third parties. For example, a symbol watermark located on the surface of a document may be visible to a person holding the document, even if only visible under certain conditions. Further, because these watermarks are located on the article surface, they can be relatively easy to apply. For these reasons, superficial watermarks can be vulnerable to discovery and forgery. For example, a counterfeit manufacturer of goods may analyze a superficial watermark on an authentic good, copy that watermark, and place the copied watermark on the manufacturer's counterfeit goods. If that watermark is used to certify the authenticity of goods, the counterfeit goods may be incorrectly certified as authentic as a result.

For these reasons, watermarks may sometimes be embedded within the surface of an article. For example, a watermark may be included between an outer layer and inner layer of an article, or embedded within a single layer of an article. In these instances, the watermark is typically not visible to the human eye without dismantling the article. For example, a watermark that is composed of metal and that is embedded beneath a surface layer of an article may only be visible through an X-ray camera, making the cost of discovering the watermark higher than most superficial watermarks. For this reason, embedded watermark may be more difficult to discover, which makes them less likely to be forged.

Further, embedded watermarks are typically more difficult to manufacture than superficial watermarks. This may, in some instances, make embedded watermarks less likely to be forged even when discovered, because the added cost of manufacturing the watermark inside the counterfeit goods may not be worthwhile. However, the added difficulty of manufacturing embedded watermarks may also cause many embedded watermarks to be simplistic in design. For example, some embedded watermarks may be a basic symbol (e.g., a square) or a basic pattern (e.g., a square grid). Unfortunately, this simplicity sometimes makes embedded watermarks less costly to forge than they otherwise would be.

Some embodiments of the present disclosure address the limitations of embedded watermarks by incorporating watermarks that are more unique than typical embedded watermarks. For example, some embodiments of the present disclosure may combine an embedded watermark (e.g., a design composed of metal strips placed beneath a surface layer of an article) with a superficial watermark. Because superficial watermarks can sometimes be made complex without significantly increasing production cost, the combination of superficial watermark and embedded watermark may both be highly detailed (thus, less likely to be accurately reproduced) and difficult to discover. Further, in some embodiments the superficial watermark may be slightly altered for each article (or group of articles) to which the watermark is applied, which may further increase the uniqueness of the combination of watermarks on each article (or group of articles). For example, in some embodiments the articles of the same manufacturing batch (i.e., produced at the same time) may contain nearly identical superficial watermarks, but the superficial watermarks may differ between articles of different manufacturing batches. As a further example, the articles produced in a particular time period (e.g., a calendar month) may all share the same watermark, but articles produced in different time periods may exhibit different watermarks.

Some embodiments of the present disclosure increase the uniqueness of embedded watermarks by incorporating metal-containing mixtures (e.g., inks, adhesives) of known and identifiable metal properties (e.g., concentrations or proportions). For example, an embedded watermark may be created beneath a superficial layer by adding ink that contains metal particles. Those metal particles may be, for example, 65% iron and 35% silver. When the embedded watermark is viewed with an X-ray camera, for example, the proportion of iron particles and silver particles may be discoverable. In another example, an embedded watermark could take the form of a hollow triangle (i.e., a closed shape composed of three lines), and each line of the triangle may be created using a different metal-containing liquid. Thus, for example, one line of the triangle may contain 50% copper and 50% iron, a second line of the triangle may contain 70% silver and 30% iron, and the third line of the triangle may contain 100% iron. In this example, each line of the triangle would have a different X-ray signature, and would therefore be more difficult to reproduce.

In some embodiments of the present disclosure, one or more metal-containing liquids may be applied beneath a superficial layer semi-randomly to make an embedded watermark. For example, an iron-containing adhesive, a silver-containing adhesive, and a gold-containing adhesive may all be sprayed at or brushed on the same spot in an interior layer of an article (e.g., a printed circuit board) in an arbitrary pattern. The resulting mixture of adhesives, and the mixtures of metals therein, may create an extremely unique X-ray signature. This may be especially true if the distribution of metals is not uniform throughout the metal-containing liquid. For example, if the distribution of iron particles throughout a sample of ink were not uniform, an identical square of ink may be placed on 1,000 different articles, but the locations of iron particles in each square may differ significantly. Thus, each otherwise identical watermark may still bear a completely unique X-ray signature. Further, because of the inherent randomness of the non-uniform distribution of iron particles in the ink, any individual watermark may be difficult to reproduce due to the difficulty of reproducing the distribution of iron particles in the watermark.

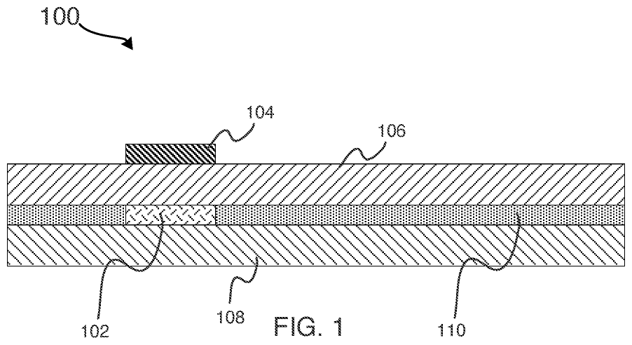

FIG. 1 illustrates an abstract representation of an article 100 with an embedded watermark 102 applied therein and a superficial watermark 104 applied thereon. Article 100 could be, for example, a multi-layer printed circuit board (sometimes referred to herein as a “PCB”), a multi-layer document, or a multi-layer physical product. First layer 106 represents an outer layer of article 100, and second layer 108 represents a second layer that is opposite first layer 106 with respect to embedded watermark 102. In some embodiments, second layer 108 may be a second outer layer. In other embodiments, second layer 108 may be an interior layer. Inner layer 110 is located between first layer 106 and second layer 108. In some embodiments, inner layer 110 may be responsible for connecting or separating first layer 106 and second layer 108. For example, inner layer 110 may take the form of a dielectric layer that adheres to and electrically insulates first layer 106 and second layer 108. In such an example, article 100 may be a printed circuit board, and first layer 106, second layer 108, and inner layer 110 may be layers within that printed circuit board. In other embodiments, inner layer may be a layer of adhesive between two sheets of paper in a multi-layer document.

Embedded watermark 102 is within inner layer 110, as illustrated. As such, embedded watermark may not be visible to the naked eye through either first layer 106 or second layer 108. Rather, embedded watermark 102 may only be visible through a specialty camera, such as an X-ray camera.

While article 100 is illustrated as having only 3 layers, some articles in which watermarks are embedded in the embodiments of the present disclosure may have more than three layers. For example, a watermark may be embedded in a printed circuit board that has 6 or more layers. Alternatively, some articles in which watermarks are embedded in the embodiments of the present disclosure may have fewer than three layers. For example, in some embodiments a watermark may be embedded within an article that has one continuous layer. For example, a watermark may be embedded in the plastic housing of an electronic device. In this example, the watermark may have been inserted into the mold of the plastic during the manufacturing process, such that the plastic housing was formed around the watermark. Thus, while the plastic housing may not have distinct layers, the watermark is still embedded therein.

As illustrated in FIG. 1, superficial watermark 104 is located “above” embedded watermark 102. In this configuration, the two watermarks together could be scanned together (e.g., with an optical camera and an X-ray camera), and may together form a complex watermark. Further, because watermark 104 may be visible with the naked eye, superficial watermark 104 may be useful for identifying the location of embedded watermark 102. In some embodiments, these two watermarks may together provide both general and specific information about article 100 that may be used to identify the article. For example, superficial watermark104 may provide a general product line (e.g., lot number) for article 100, and embedded watermark 102 may provide a specific machine ID number.

The form of superficial watermark 104 may vary based on the use case. In some embodiments, for example, superficial watermark 104 may be printed or written on first layer 106 in an ink that is visible to the naked eye. In other embodiments, superficial watermark 104 may only be visible when treated with certain equipment (for example, when ultra-violet light is shined on superficial watermark 104). Superficial watermark may also only be visible using X rays. For example, superficial watermark 104 may be a fluid (such as an adhesive) that contains metal particles. The pattern of these metal particles (which may not be visible to the naked eye) may be visible when viewed using an X-ray camera.

The form of embedded watermark 102 may also vary based on the use case. For example, embedded watermark 102 could take the form of metal foil or one or more metal wires that are arranged in a pattern, such as square grid or a spiral. Embedded watermark 102 could also take the form of mixture that contains metal particles. This mixture may be non-solid when applied (e.g., a liquid or paste), but may solidify over time. For example, embedded watermark 102 could take the form of an ink or adhesive that contains copper particles or a mixture of nickel particles and osmium particles. In some such embodiments, the concentration of the metal particles (and the relative proportions thereof), and the pattern of the particles within the liquid may all contribute to the uniqueness and identifiability of the watermark.

Finally, while article 100 discloses both an embedded watermark and a superficial watermark, some embodiment of the present disclosure utilize articles that contain only an embedded watermark. For example, embedded watermark 102 may take the form of a liquid containing metal particles. That liquid may be painted onto/into inner layer 110 in an arbitrary (or even random) shape during manufacturing of article 100. After article 100 had been manufactured and assembled, an X-ray camera may be used to view embedded watermark 102 and record the spatial distribution of metal particles within watermark 102. This distribution of metal particles may be unique and random enough that embedded watermark 102 may be very difficult to forge, and therefore superficial watermark 104 may be omitted. However, in some embodiments, superficial watermark 104 may still be preferred in order to provide the location of embedded watermark 102.

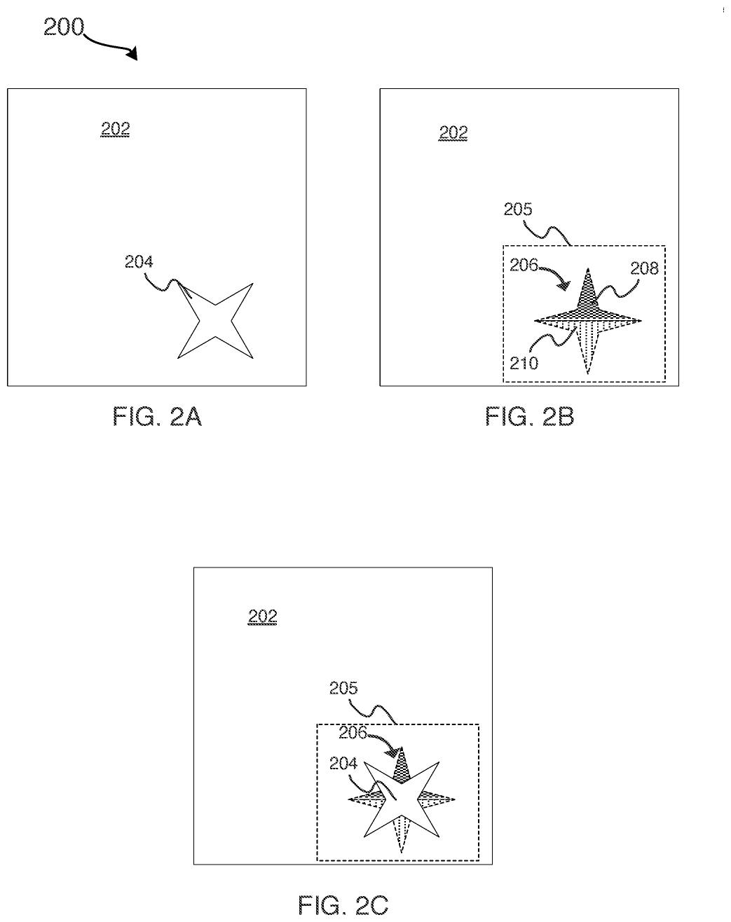

FIG. 2A through FIG. 2C illustrate multiple views of an article 200 with an embedded and superficial watermark. FIG. 2A illustrates a view of article 200 as may be recorded by an optical camera. Article 200 includes outer surface 202. Outer surface 202 may be, for example, the exterior of a printed circuit board, the outer layer of a sticker, of the exterior of a product housing. Visible on outer surface 202 is superficial watermark 204. Superficial watermark 204 could, for example, take the form of ink that is visible to the naked eye in natural sunlight or visible to the naked eye under other lighting conditions (e.g., with ultraviolet light). In other embodiments, superficial watermark 204 could be visible only with the use of special camera equipment, such as an X-ray camera.

FIG. 2B illustrates a view of article 200 as may be recorded by an X-ray camera. FIG. 2B therefore illustrates a view that displays the interior of article 200 beneath outer surface 202 (assuming that outer surface 202 is composed of a material that X-rays are capable to penetrate). For the sake of understanding, X-ray border 205 illustrates the area of outer surface 202 that an X-ray camera is focusing on (and has thus rendered transparent). However, in some embodiments, an X-ray camera may focus on other portions of surface 202, including the entire surface 202 FIG. 2B thus illustrates embedded watermark 206, which is depicted as surrounded by a dotted line to emphasize that embedded watermark 206 is located inside article 200. Embedded watermark 206 may be a metal foil, a collection of metal wire, or a mixture that contains metal particles that was drawn on an interior layer of article 200 during manufacturing or assembly.

Embedded watermark 206 is composed of two sections: section 208 and section 210. Sections 206 and 208 are illustrated as having different X-ray signatures, which increases the complexity of embedded watermark 206. For example, section 208 and section 210 may be foils of different types of metal that have different X-ray signatures. Section 208 and section 210 may be two different adhesive mixtures that have different concentrations of iron particles within them, causing sections 206 and section 210 to appear differently on the X-ray camera. Section 208 and section 210 may also be different ink mixtures that have different metal particles mixed therein (for example, the ink in section 208 may have iron mixed in, whereas the ink in section 210 may have platinum mixed in).

FIG. 2C illustrates a view of article 200 in which the view of article 200 from an optical camera (for example, the view of FIG. 2A), is superimposed with the view of an X-ray camera (for example, the view depicted by X-ray border 205 of FIG. 2B). As such, FIG. 2C illustrates superficial watermark 204 superimposed over embedded watermark 206. The relative positions and properties of these two watermarks may be used for unique identification purposes (e.g., certifying a good as genuine), consistent with embodiments described within the present disclosure. For example, the combined shape of the watermarks may be used for authentication, as may the proportions of the watermarks that overlap, the proportions of watermarks that do not overlap, or others.

While, in FIGS. 2A through 2C superficial watermark 204 is located directly “over” embedded watermark 206, in some embodiments other positional relationships are possible. For example, in some embodiments superficial watermark 204 and embedded watermark 206 may not overlap, but may be within a pre-determined distance of each other. In some embodiments, superficial watermark 204 and embedded watermark 206 may be adjacent to each other when the images are superimposed, such that superficial watermark 204 and embedded watermark 206 form one shape in FIG. 2C.

In some embodiments, article 200 may actually contain multiple embedded watermarks. For example, when viewed from above using an X-ray camera, article 200 may contain an embedded watermark in each corner. In these embodiments, a superficial watermark may provide information regarding which embedded watermark could be used for identification purposes.

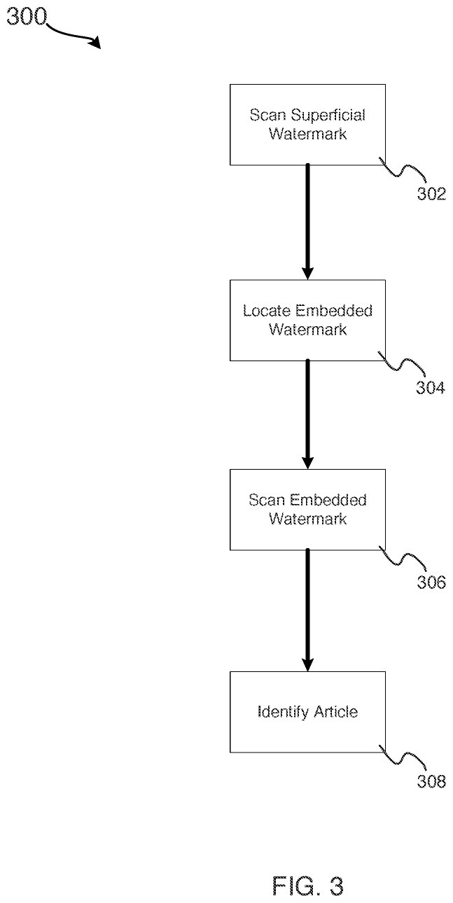

FIG. 3 discloses a method 300 by which a superficial watermark and embedded watermark (such as the watermarks on article 200) could jointly be used for identification purposes, such as determining an article's unique identity, determining a class into which the article falls, or certifying the authenticity of the article. Method 300 may be performed by a computer system that is connected to an optical camera and an X-ray camera. In some embodiments, the computer system may also have access to a database of watermark images, or properties thereof, that can be compared to the properties of watermarks on or in an article for certification or unique identification purposes.

Method 300 begins with block 302, in which a surface watermark on the article is scanned. In some embodiments, scanning a superficial watermark may include performing an analysis of the watermark to obtain information regarding the watermark or the article. For example, the superficial watermark may provide the manufacturing location of the article. The superficial watermark may also provide information regarding a watermark that is embedded within the article. For example, in some embodiments the superficial watermark may contain a pre-determined symbol if the article contains an embedded watermark, and a different pre-determined symbol if the article does not contain an embedded watermark. In some embodiments, the superficial watermark may provide an information regarding the location of an embedded watermark. For example, some superficial watermarks may specify that an embedded watermark is located directly beneath the superficial watermark. Some superficial watermarks may specify that an embedded watermark is elsewhere on (or in) the article. The superficial watermark may also provide information regarding the form of an embedded watermark. For example, the superficial watermark may specify that the embedded watermark is metal foil, wire, or a mixture of resin and silver particles.

Method 300 continues with block 304, in which an embedded watermark is located. In some embodiments, the embedded watermark may be located based on information identified in an analysis of the superficial watermark. In some embodiments, the embedded watermark may be located based on other information, such as the product type, or by searching the entire article for indications of an embedded watermark (for example, by scanning the article with an X-ray camera). In some embodiments, the inability to locate an embedded watermark in block 304 may result in an article not being identified.

If, on the other hand, an embedded watermark is located, the embedded watermark is scanned in block 306. In some embodiments, this scan may compare the properties of the embedded watermark with the properties of embedded watermarks that were analyzed when the containing articles were originally certified as authentic (for example, during the manufacturing process. For example, patterns of distributed metal particles within the watermark may be compared with a database of images of previously recorded watermarks to find a similar (or identical) distribution of metal particles. The patterns of distributed metal particles may also be converted to computer-readable, structured data (e.g., a vector) and compared with structured data that describes previously recorded distributions of metal particles.

In some embodiments, scanning the embedded watermark in block 306 may also include scanning the superficial watermark at the same time, such that the superficial watermark and the embedded watermark may be considered together. In some embodiments, the embedded watermark may be scanned separately, but the information identified from the analysis of the scan in block 306 may be considered in combination with the scan of the superficial watermark in block 302. In some embodiments, the information identified by scanning the embedded watermark may be independent of the superficial watermark, and discovering that information, therefore, may not be affected by the scan of the superficial watermark.

Once the embedded watermark is scanned in block 306, the article is identified in block 308. In some embodiments, this identification process is based on whether the information identified from the embedded watermark matches information previously recorded as genuine. For example, block 308 may involve determining the shape that the superficial watermark and the embedded watermark make together when an image of the article recorded by an optical camera is superimposed over an image of the article recorded by an X-ray camera. For example, the two watermark images placed together may compose a pre-determined image, such as a person's face or a complex shape.

In some embodiments, the identification process in block 308 may solely analyze the properties of the embedded watermark. For example, in some embodiments the identification process may determine whether the embedded watermark contains the correct concentration or proportion of metal particles. In some embodiments, the identification process may determine whether certain sections of the embedded watermark contain the correct concentration or proportion of metal particles.

As noted previously, a process similar to method 300 may be useful to uniquely identify, rather than to authenticate, articles. For example, in some embodiments each article produced by a manufacturer may have a unique device identification number, and each unique identification number may be paired with a unique watermark. This may be accomplished, for example, by making a unique watermark using an ink that has an unevenly distributed collection of metal particles mixed therein. This may cause the pattern of metal-particle distribution in a final watermark to have a high amount of randomness, which may also result in a high amount of uniqueness. For this reason, it may be beneficial to use the resulting unique watermarks as unique identification of articles.

Further, while method 300 is disclosed as involving a superficial watermark, in some embodiments a similar method may be performed that does not scan or analyze a superficial watermark. For example, when authenticating or uniquely identifying an article, the entire article may be scanned by an x-ray camera to determine whether an embedded watermark exists, and, if so, where the embedded watermark is located. In some embodiments an x-ray camera may take a picture of the entire article, and any embedded watermarks within the picture may be analyzed for identification purposes.

In some embodiments of the present disclosure, identifying an article with an embedded watermark relies on the properties of the embedded watermark being recorded previously (for example, during manufacturing). For example, analyzing a watermark may include comparing an image of that watermark, or the properties of the watermark discernable by that image (e.g., the concentration of metal particles within a watermark) to a database of images of watermarks or properties of watermarks that have been previously recorded.

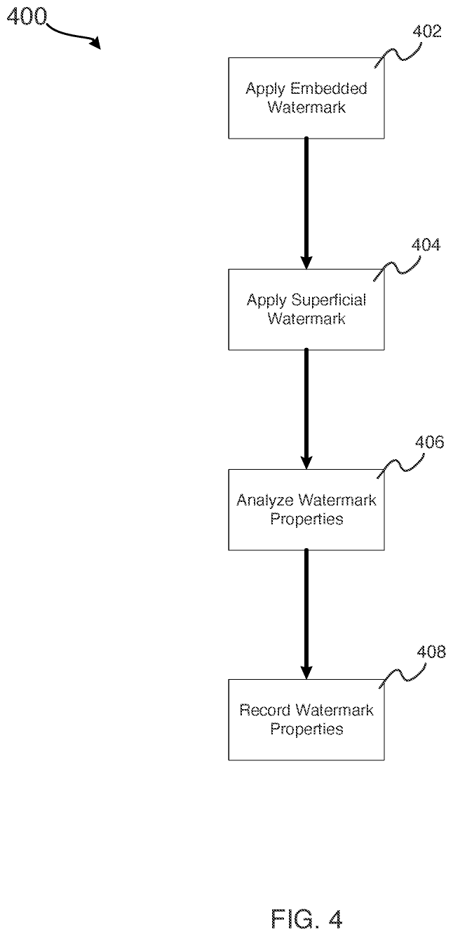

FIG. 4 illustrates a method 400 of recording the properties of one or more watermarks for later identification purposes. Method 400 may be performed, for example, during product assembly or manufacturing, and may be performed by a computer system that has access to an optical and/or X-ray camera. Method 400 begins in block 402, in which an embedded watermark is applied to an article. This may include, for example, drawing on an inner layer of an article with metal-containing ink, etching a metal wire or foil on an inner layer of an article, or molding an article (or portion thereof) around a metal watermark.

Method 400 continues in block 404, in which a superficial watermark is applied to the article. In some embodiments, this may occur at a later stage in a manufacturing process than block 402. For example, an embedded watermark may be applied to an inner layer of a printed circuit board early in the fabrication process, and a superficial watermark may be applied to the outer layer of a plastic housing into which the circuit board is packaged. In a similar example, the embedded watermark may be applied to an inner layer of a printed circuit board, and the superficial watermark may be applied to the outermost layer of the printed circuit board during a solder-masking process.

In some embodiments, block 404 may include applying the superficial watermark at a location on the article that corresponds to the embedded watermark. For example, the superficial watermark may be applied in a location that directly overlaps the embedded watermark when the article is viewed from a pre-determined angle.

Once the superficial watermark is applied, the watermark properties are analyzed in block 406. In some embodiments, this may involve analyzing the properties of both the superficial watermark and the embedded watermark. In other embodiments, this may involve solely analyzing the embedded watermark properties. In some embodiments block 406 may analyze the shape of one or both of the watermarks, either individually or when superimposed upon each other (for example, when an image of each watermark is created by one or more cameras). In some embodiments, block 406 may also analyze the properties of an X-ray signature of one or both of the watermarks. These properties may include the concentration of metal particles throughout the watermark or at certain locations of the watermark, the types of metals detected in watermark in the X-ray image, and the proportions of metals within the watermark. In some embodiments, block 406 may analyze the portions of the superficial watermark and the embedded watermark that overlap when images of the watermarks are superimposed over each other. In some embodiments block 406 may analyze the portions of the superficial watermark and the embedded watermark that do not overlap. These examples are not meant to be exhaustive; other analyses of watermark properties that are otherwise consistent with the spirit and scope of the embodiments of the present disclosure are also contemplated.

Once the watermark properties are analyzed in block 406, the watermark properties are recorded in block 408. In some embodiments, recording the watermark properties in block 408 may include storing the properties in a database that a computer system configured to perform an identification process may have access. In some embodiments, recording the watermark properties may include storing an image of the watermark or watermarks. In some embodiments, computer-readable structured data of the watermark or watermarks may be stored. These structured data may include a vector that describes an image of the watermark. These structured data may also include measured properties of the watermark, such as the watermark's dimensions, location of the watermark compared to other watermarks, or a number signifying the concentration of metal ions in the watermark.

While method 400 is illustrated as including a superficial watermark, methods similar to method 400 may be utilized to record solely embedded-watermark properties. In these methods, block 406 may only analyze embedded watermark properties and block 408 may only record embedded watermark properties. Some of these methods may be performed for articles that have no superficial watermark present, and only contain one or more embedded watermarks. In these methods, block 404 may not be performed.

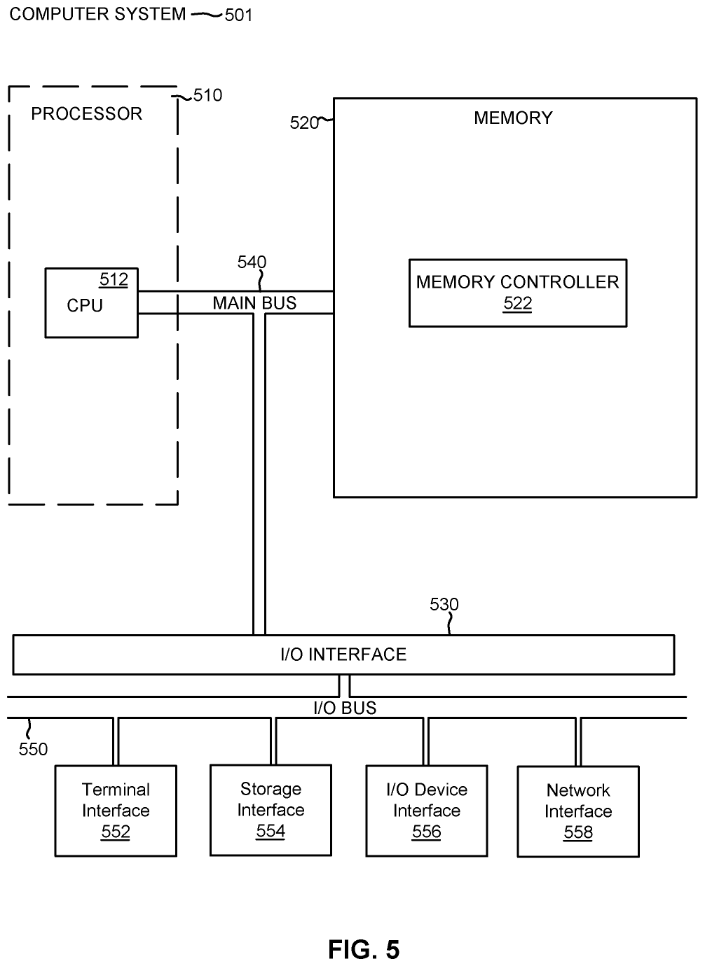

FIG. 5 depicts the representative major components of an example Computer System 501 that may be used in accordance with embodiments of the present disclosure. The particular components depicted are presented for the purpose of example only and are not necessarily the only such variations. The Computer System 501 may include a Processor 510, Memory 520, an Input/Output Interface (also referred to herein as I/O or I/O Interface) 530, and a Main Bus 540. The Main Bus 540 may provide communication pathways for the other components of the Computer System 501. In some embodiments, the Main Bus 540 may connect to other components such as a specialized digital signal processor (not depicted).

The Processor 510 of the Computer System 501 may include one or more CPUs 512. The Processor 510 may additionally include one or more memory buffers or caches (not depicted) that provide temporary storage of instructions and data for the CPU 512. The CPU 512 may perform instructions on input provided from the caches or from the Memory 520 and output the result to caches or the Memory 520. The CPU 512 may include one or more circuits configured to perform one or methods consistent with embodiments of the present disclosure. In some embodiments, the Computer System 501 may contain multiple Processors 510 typical of a relatively large system. In other embodiments, however, the Computer System 501 may be a single processor with a singular CPU 512.

The Memory 520 of the Computer System 501 may include a Memory Controller 522 and one or more memory modules for temporarily or permanently storing data (not depicted). In some embodiments, the Memory 520 may include a random-access semiconductor memory, storage device, or storage medium (either volatile or non-volatile) for storing data and programs. The Memory Controller 522 may communicate with the Processor 510, facilitating storage and retrieval of information in the memory modules. The Memory Controller 522 may communicate with the I/O Interface 530, facilitating storage and retrieval of input or output in the memory modules. In some embodiments, the memory modules may be dual in-line memory modules.

The I/O Interface 530 may include an I/O Bus 550, a Terminal Interface 552, a Storage Interface 554, an I/O Device Interface 556, and a Network Interface 558. The I/O Interface 530 may connect the Main Bus 540 to the I/O Bus 550. The I/O Interface 530 may direct instructions and data from the Processor 510 and Memory 520 to the various interfaces of the I/O Bus 550. The I/O Interface 530 may also direct instructions and data from the various interfaces of the I/O Bus 550 to the Processor 510 and Memory 520. The various interfaces may include the Terminal Interface 552, the Storage Interface 554, the I/O Device Interface 556, and the Network Interface 558. In some embodiments, the various interfaces may include a subset of the aforementioned interfaces (e.g., an embedded computer system in an industrial application may not include the Terminal Interface 552 and the Storage Interface 554).

Logic modules throughout the Computer System 501—including but not limited to the Memory 520, the Processor 510, and the I/O Interface 530—may communicate failures and changes to one or more components to a hypervisor or operating system (not depicted). The hypervisor or the operating system may allocate the various resources available in the Computer System 501 and track the location of data in Memory 520 and of processes assigned to various CPUs 512. In embodiments that combine or rearrange elements, aspects of the logic modules' capabilities may be combined or redistributed. These variations would be apparent to one skilled in the art.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. An article comprising:
a superficial watermark located on a first surface; and
an embedded watermark embedded within the article;
wherein the embedded watermark may be viewed by an x-ray camera.

2. The article of claim 1, wherein the embedded watermark is located between two layers of the article.

3. The article of claim 1, wherein the superficial watermark provides information that identifies the location of the embedded watermark.

4. The article of claim 1, wherein an image of the superficial watermark superimposed over the embedded watermark provides an identification of the article.

5. The article of claim 1, wherein the embedded watermark comprises a mixture of metal particles.

6. The article of claim 1, wherein the embedded watermark comprises a metal foil.

7. The article of claim 1, wherein the embedded watermark uniquely identifies the article.

8. The article of claim 1, wherein the superficial watermark provides general information about the article.

9. An article comprising:
an embedded watermark embedded within the article, wherein the embedded watermark comprises an identifiable mixture of metal particles.

10. The article of claim 9, wherein a property of the identifiable mixture of metal particles provides information regarding the article.

11. The article of claim 10, wherein the property of the identifiable mixture comprises the concentration of a first metal element within the identifiable mixture.

12. The article of claim 10, wherein the property of the identifiable mixture comprises a proportion of a second metal element and a third metal element within the mixture.

13. The article of claim 10, wherein the metal particles form a shape, and the property of the identifiable mixture comprises a dimension of the shape.

14. The article of claim 9, wherein the article is a printed circuit board, and the embedded watermark is located between two layers of the printed circuit board.

15. A method comprising:
applying a metal-containing mixture to an inner layer of an article, resulting in an embedded watermark within the article;
analyzing a first property of metal particles of the mixture; and
recording the first property.

16. The method of claim 15, wherein the first property comprises an identify of a first metal element within the mixture.

17. The method of claim 15, wherein the first property comprises a concentration of metal particles within the mixture.

18. The method of claim 15, wherein the first property comprises a proportion of a second metal element and a third metal element within the mixture.

19. The method of claim 15, further comprising:
applying a superficial watermark to a surface of the article;
analyzing a second property of the superficial watermark; and
recording the second property.

20. The method of claim 19, wherein analyzing the second property comprises superimposing an image of the superficial watermark and an image of the embedded watermark, and wherein the second property comprises the proportion of the superficial watermark that overlaps the embedded watermark.
